(19) United States
(12) Patent Application Publication
(10) Pub. No.: US 2024/0347373 A1
(43) Pub. Date: Oct. 17, 2024

(54) DEVICE FOR HOLDING A PACKAGE SUBSTRATE WITH REDUCED WARPAGE

(71) Applicant: STATS ChipPAC Pte. Ltd., Singapore (SG)

(72) Inventors: JongChan PARK, Incheon (KR); YoungMin KIM, Incheon (KR); GilHo LEE, Incheon (KR); HyeongKwan KIM, Incheon (KR); TaeKeun LEE, Incheon (KR)

(21) Appl. No.: 18/636,304

(22) Filed: Apr. 16, 2024

(30) Foreign Application Priority Data
Apr. 17, 2023 (CN) 202310408194.8

(51) Int. Cl. H01L 21/687; H01L 21/68

(52) U.S. Cl. CPC H01L 21/68785; H01L 21/68

(57) ABSTRACT

A device for holding a package substrate is provided. The device comprises: a lower jig comprising a base material, and magnets embedded within the base material; and an upper jig comprising a frame and a grid pattern inside the frame, wherein the frame has a skirt portion that defines a gap between the lower jig and the grid pattern to accommodate the package substrate, and wherein the grid pattern is attractable by the magnets such that when the upper jig is placed on the lower jig to accommodate the package substrate the grid pattern is in contact with the package substrate to apply a pressure to the package substrate due to a magnetic interaction between the magnets and the grid pattern.

### TECHNICAL FIELD

The present application generally relates to semiconductor technologies, and more particularly, to a device for holding a package substrate with improved warpage control.

### BACKGROUND OF THE INVENTION

When semiconductor dice are packaged into a semiconductor package, they may be attached and bonded onto a package substrate via solder bumps or similar structures. A reflow process may be desired to melt the solder bumps that interconnect the semiconductor dice with the package substrate. However, as heat is applied to the package substrate during the reflow process, the package substrate may warp and thus bulge from a carrier when it is placed. The warpage of the package substrate may cause irregular joints and bump cracks, thereby leading to a low yield.

Jigs may be used to resolve the warpage of package substrates. For example, a lower jig and an upper jig may sandwich the package substrate therebetween, to press the package substrate especially at positions with large warpages. However, the conventional jigs cannot satisfactorily reduce severe warpage, especially for thinner package substrates.

Therefore, a need exists for a device for holding a package substrate with improved warpage control.

### SUMMARY OF THE INVENTION

An objective of the present application is to provide a device for holding a package substrate with improved warpage control.

According to an aspect of the present application, a device for holding a package substrate is disclosed. The device comprises: a lower jig comprising a base material, and magnets embedded within the base material; and an upper jig comprising a frame and a grid pattern inside the frame, wherein the frame has a skirt portion that defines a gap between the lower jig and the grid pattern to accommodate the package substrate, and wherein the grid pattern is attractable by the magnets such that when the upper jig is placed on the lower jig to accommodate the package substrate the grid pattern is in contact with the package substrate to apply a pressure to the package substrate due to a magnetic interaction between the magnets and the grid pattern.

According to another aspect of the present application, a device for holding package substrates is disclosed. The device comprising a plurality of seats, and each seat comprises: a lower jig comprising a base material, and magnets embedded within the base material; and an upper jig comprising a frame and a grid pattern inside the frame, wherein the frame has a skirt portion that defines a gap between the lower jig and the grid pattern to accommodate the package substrate, and wherein the grid pattern is attractable by the magnets such that when the upper jig is placed on the lower jig to accommodate the package substrate the grid pattern is in contact with the package substrate to apply a pressure to the package substrate due to a magnetic interaction between the magnets and the grid pattern.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A and 1B illustrate a device 100 for holding a package substrate 10 according to an embodiment of the present application. FIG. 1A is a top view of the device 100, and FIG. 1B is a cross sectional view of the device 100 along line AA′ in FIG. 1A.

FIG. 1C shows an enlarged view of a zone V in FIG. 1B.

FIGS. 2A and 2B illustrates two exemplary layouts of magnets in a lower jig according to embodiments of the present application.

FIGS. 3A to 3C illustrate a device 300 for holding a package substrate 30 according to an embodiment of the present application. FIG. 3A is a cross sectional view of the device 300, and FIGS. 3B and 3C are bottom views of two exemplary upper jigs of the device 300 according to the embodiments of the present application.

FIGS. 4A and 4B illustrate a device 400 for holding package substrates according to an embodiment of the present application. FIG. 4A shows a lower jig 402 of the device 400 and FIG. 4B shows an upper jig 404 of the device 400.

FIG. 5 is a test result comparing the warpage of a package substrate held by a conventional device (DOE #1) without magnetic interactions in the active region of the package substrate with the warpages of package substrates held by four devices (DOE #2 to DOE #5) according to some examples of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another clement, it may be directly connected to or coupled to the other element, or intervening elements may be present.

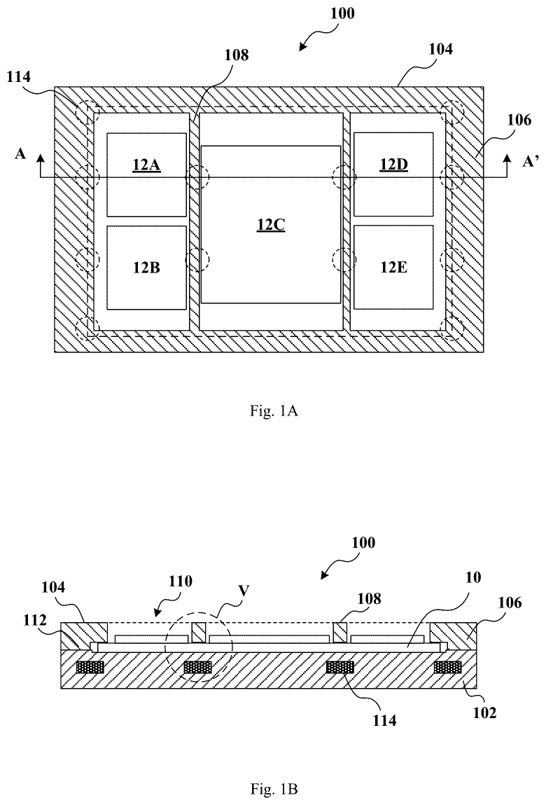

FIGS. 1A and 1B illustrate a device 100 for holding a package substrate 10 according to an embodiment of the present application. FIG. 1A is a top view of the device 100, and FIG. 1B is a cross sectional view of the device 100 along line AA′ in FIG. 1A.

In some embodiments, the package substrate 10 may be attached with various electronic components 12A to 12E shown in FIG. 1A. The electronic components 12A to 12E may include any of a variety of types of semiconductor dice, semiconductor packages, or discrete devices. For example, the electronic components 12A to 12E may include one or more digital chips, analog chips or mixed signal chips, such as application-specific integrated circuit (“ASIC”) chips, sensor chips, wireless and radio frequency (RF) chips, memory chips, logic chips or voltage regulator chips. The electronic components 12A to 12E may also include one or more passive electrical components such as resistors, capacitors, inductors, etc. In some embodiments, the electronic components 12A to 12E may include an integrated circuit chip for wireless communication and/or signal processing, which may require antennas for transmitting and receiving wireless signals. In some embodiments, the electronic components 12A to 12E may further include output and/or input circuits for an antenna structure for wireless communication.

The electronic components may be attached on the package substrate 10 in a specific layout, depending on the sizes of the electronic components 12A to 12E and the package substrate 10. For example, in the embodiment shown in FIG. 1A, the biggest electronic component 12C is at the center of the package substrate 10, while the other four electronic components 12A, 12B, 12D and 12E are at four corners of the package substrate 10 which are relatively outer than the biggest electronic component 12C. It can be appreciated there may be package substrates with other layouts of electronic components. For example, the biggest electronic component 12C may be disposed in a left region while the other four smaller electronic components 12A, 12B, 12D and 12E may be disposed in a right region of the package substrate 10. However the electronic components are attached on the package substrate 10, a portion of the package substrate 10 is exposed between each two adjacent electronic components. The portion of the package substrate 10 attached with the electronic components may be referred to as active region, while the exposed portion of the package substrate 10 may be referred to as non-active region. It can be appreciated that due to the mechanical and material properties of the electronic components and the package substrate, it is applicable to apply a pressure or force to the non-active region, rather than to the active region of the package substrate.

The electronic components 12A to 12E may be attached onto the package substrate 10 via bonding such as solder bumps, and thus a reflow process or other similar heating or curing process may be desired to be performed to the package substrate 10, when the package substrate 10 is held by the device 100. In some embodiments, the package substrate 10 may include one or more dielectric layers, with conductive layers and vias (not shown) formed in the dielectric layers. For example, the dielectric layers may be laminated films that are laminated to each other. Due to the composite composition of the package substrate 10, it may warp when heat is applied during a reflow process, for example.

As illustrated in FIGS. 1A and 1B, the device 100 includes a lower jig 102 and an upper jig 104 which are operable to hold the package substrate 10 therebetween. The lower jig 102 has a base material which is formed of a dielectric material, a metal, or the like. The lower jig 102 may be a plate on which the package substrate 10 can lie flat. In some embodiments, the lower jig 102 may be slightly recessed in its central region, to receive the package substrate 10 and prevent it from sliding off the lower jig 102, for example, when the lower jig 102 tilts a little. In some alternative embodiments, the lower jig 102 may have a flat top surface.

In some embodiments, the upper jig 104 may be formed of a ferromagnetic material such as steel, which may be attracted by a magnetic field disposed in the lower jig 102 as will elaborated below. In some other embodiments, a portion of the upper jig 104, rather than an entirety of the upper jig 104, may be formed of a ferromagnetic material. For example, the upper jig 104 may have a base material of a dielectric material such as rubber or plastics, or a metal such as copper, and a bottom material of a ferromagnetic material attached to the base material and closer to the lower jig 102 when the upper jig 104 is placed on the lower jig 102. In some preferred embodiments, a coating layer of silicone or other similar elastomeric material may be disposed under the bottom material to buffer between the lower jig 102 and the package substrate 10 on the upper jig 104.

The upper jig 104 may have a shape and size substantially the same as the lower jig 102, such that the two jigs 102 and 104 can be aligned and attached with each other. In particular, the upper jig 104 may have a frame 106 in its peripheral region and a grid pattern 108 in its central region. The grid pattern 108 may extend substantially along a plane defined by the frame 106, except that the frame 106 may have a skirt portion 112 extending downward. When the upper jig 104 is placed on the lower jig 102, the skirt portion 112 may define a gap between the lower jig 102 and the grid pattern 108 to accommodate the package substrate 10. Therefore, the skirt portion 112 may have a thickness substantially equal to or slightly smaller than a thickness of the package substrate 10 (not including the electronic components 12A to 12E mounted thereon). In the embodiment where the lower jig 102 may be recessed in its central region, a sum of the thickness of the skirt portion 112 and a depth of the recess of the lower jig 102 may be substantially equal to or slightly smaller than the thickness of the package substrate 10. In this way, a clamping force may be applied to the package substrate 10 at its periphery through the lower and upper jigs 102 and 104, without leading to any damages to the electronic components 12A to 12E.

The grid pattern 108 may have a plurality of openings 110. The openings 110 may be big enough to allow the electronic components 12A to 12E to expose through the grid pattern 108. In that case, no pressure may be applied to the electronic components 12A to 12E by the upper jig 104, thereby damages to the electronic components 12A to 12E can be avoided. In the embodiment shown in FIGS. 1A and 1B, the grid pattern 108 of the upper jig 104 has two ribs that extend in parallel with each other between a pair of edges of the frame 106. The ribs and the edges of the frame 106 define three openings 110 which expose the electronic components 12A and 12B, the electronic component 12C, and the electronic components 12D and 12E, respectively. It can be appreciated that the grid pattern 108 may have more ribs or may have other layouts. For example, another rib may be formed in the grid pattern 108 and above the exposed portion of the package substrate between the electronic components 12A and 12B, or between the electronic components 12D and 12E. More ribs in the grid pattern may produce a stronger and more uniform pressure to the package substrate, which is beneficial for the mitigation of warpages of the package substrate, as elaborated below.

In some embodiments, when the package substrate 10 is inserted between the lower jig 102 and the upper jig 104, each of the ribs of the grid pattern 108 may be in contact with the package substrate 10 so as to apply a pressure onto the package substrate 10 in its active region. However, in some cases where the package substrate 10 may have a thickness slightly smaller than the gap between the lower and upper jigs 102 and 104, the grid pattern 108 or particularly its ribs may not be in contact with the top surface of the package substate 10, or may not apply a pressure of a desired strength to the package substrate 10 for mitigating the warpage of the package substrate 10. Accordingly, one or more magnets 114 may be embedded within the base material of the lower jig 102, as shown in FIGS. 1A and 1B. In a preferred embodiment, the magnets 114 may be disposed in the lower jig 102 corresponding to positions of the ribs of the grid pattern 108 and the frame 106. In this way, the magnets 114 may be close to the ribs and the frame 106 when the lower jig 102 and the upper jig 104 are attached with each other, the magnets 114 can attract the ferromagnetic material of the upper jig 104, so as to increase the pressure applied to the package substrate 10 through the ribs and frame 106. FIG. 1C shows an enlarged view of a zone V in FIG. 1B, which illustrates the pressure or force applied to the package substrate 10 through the ribs and frame 106, to overcome the bulged portion of the package substrate 10.

In the embodiment shown in FIG. 1A, the magnets 114 includes two columns of magnets disposed at the frame 106, and another two columns of magnets disposed at the respective two ribs of grid pattern 108. It can be appreciated that more or less magnets may be embedded in the lower jig 102, depending on the layout of the grid pattern 108. In some examples, each magnet 114 may have a circular shape, or be of a rectangular, square or any other suitable shape. A distance from each magnet 114 to a top surface of the lower jig 102 may be 0.2 mm to 20 mm, for example, to allow for a proper magnetic interaction between the magnets and the upper jig 104. In some embodiments, the magnets 114 may be permanent magnets, while in some alternative embodiments, the magnets 114 may be electromagnets which can be activated or disactivated by a power supply. In addition, in the embodiments where the magnets 114 may be electromagnets, a strength of the magnetic field produced by the magnets 114 may be adjustable by a control circuit for the power supply. In this way, the strength of the magnetic field may be adjusted less to mitigate smaller warpages, or greater to mitigate bigger warpages. Optionally, a warpage detection apparatus may be used to detect the warpages of the package substrate 10 at different positions to adjust the magnetic field.

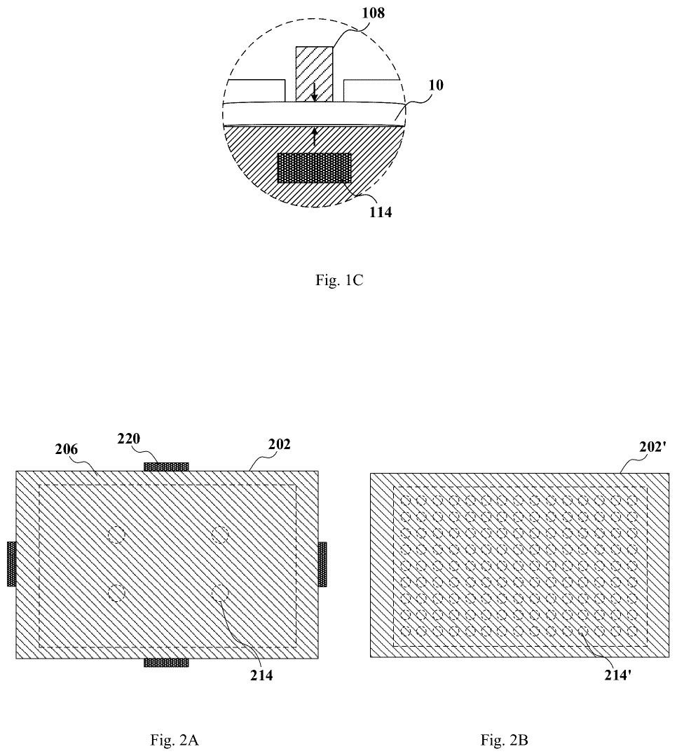

Although it is shown in FIG. 1A that the magnets 114 may be disposed below both the frame 106 and the grid pattern 108, in some alternative embodiments, the magnets 114 may be disposed only below the grid pattern 108, as shown a lower jig 202 shown in FIG. 2A. In that case, other fasteners 220 such as clamps, pins or clips may be arranged at a frame 206 of the lower jig 202 or around the frame 206 to secure the lower jig 202 with an upper jig and maintain a package substrate therebetween.

In some other embodiments, the magnets may be distributed across the lower jig with a finer pitch. FIG. 2B illustrates an exemplary layout of magnets in a lower jig according to an embodiment of the present application, which has a layout of magnets with a finer pitch. As shown in FIG. 2B, an array of magnets 214′ are disposed in a lower jig 202′. Although not all of the magnets 214′ in the lower jig 202′ may be accurately aligned with the ribs or other similar protrusions extending downward from the upper jig (not shown), each of the ribs or other similar protrusions of the upper jig can be aligned with some of the magnets 214′ in the lower jig 202′and thus sufficient magnetic interaction can be maintained between the lower jig 202′ and the upper jig. A lower jig with excess magnets such as the lower jig 202′ shown in FIG. 2B can allow the use of the lower jig with various upper jigs having different grid patterns, to hold package substrate with different layouts.

In some embodiments, the upper jig 104 may include one or more magnets that may be embedded within the grid pattern 108, especially close to or within the ribs or other similar protrusion structures. These magnets may further improve the magnetic interaction with the magnets in the lower jig 102.

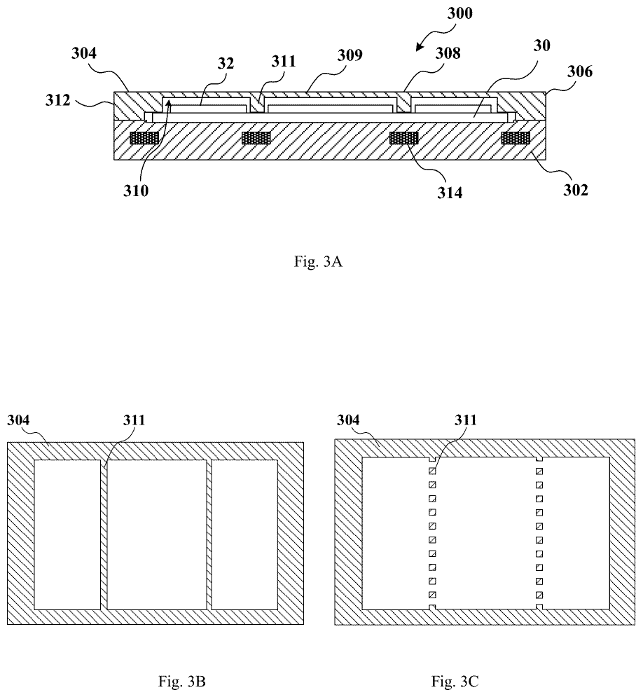

FIGS. 3A to 3C illustrate a device 300 for holding a package substrate 30 according to an embodiment of the present application. FIG. 3A is a cross sectional view of the device 300, and FIGS. 3B and 3C are bottom views of two exemplary upper jigs of the device 300 according to the embodiments of the present application.

As shown in FIG. 3A, the device 300 includes a lower jig 302 and an upper jig 304. The lower jig 302 may be the same as or similar to the lower jig 102 shown in FIGS. 1A and 1B, where a plurality of magnets 314 are embedded for attraction purpose. However, the upper jig 304 may be of a different structure from the upper jig 104 shown in FIGS. 1A and 1B.

In particular, the upper jig 304 may have a frame 306 and a grid pattern 308. The frame 306 has a skirt portion 312 which defines a gap between the lower jig 302 and the grid pattern 308 to accommodate the package substrate 30. The grid pattern 308 may have a cover plate 309 and a plurality of protrusions 311 that extend from the cover plate 309. The protrusions 311 may take the form of ribs that are continuously shaped as shown in FIG. 3B, or take the form of pins that are discontinuously shaped as shown in FIG. 3C. The protrusions 311, whether take the form of ribs or pins, may be in contact with the package substrate 30 when the upper jig 304 is placed on the lower jig 302 due to the magnetic interaction between the magnets 314 and the upper jig 304. In this way, the protrusions 311 may apply a pressure to the package substrate 30 to mitigate the warpage of the package substrate 30.

As shown in FIG. 3A, the package substrate 30 may be attached with electronic components 32. The cover plate 309 and the protrusions 311 of the upper jig 304 may define cavities 310 to accommodate the electronic components 32, to at least avoid the electronic components from being pressed by the upper jig 304 when the package substrate 30 is held by the device 300. It can be appreciated that the protrusions 311 may be inserted between the electronic components 32 and in contact with the exposed portions of a top surface of the package substrate 30 to apply the pressure or force to the package substrate 30.

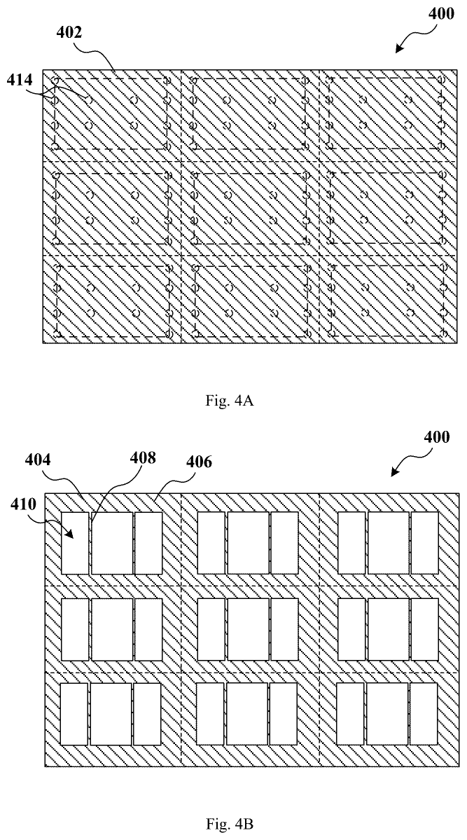

FIGS. 4A and 4B illustrate a device 400 for holding package substrates according to an embodiment of the present application. FIG. 4A shows a lower jig 402 of the device 400 and FIG. 4B shows an upper jig 404 of the device 400. As shown in FIGS. 4A and 4B, the device 400 has nine seats, each of which can accommodate and hold a package substrate for processing such as reflow processing, in a manner similar to the device 100 shown in FIGS. 1A and 1B. In particular, as shown in FIG. 4A, the lower jig 402 may have a set of magnets 414 embedded within a base material of the lower jig, where package substrates can be placed. The upper jig 404 may have a shape and size substantially the same as the lower jig 402, such that the two jigs 402 and 404 can be aligned and attached with each other. In particular, the upper jig 404 may have a frame 406 in a peripheral region of each seat and a grid pattern 408 in a central region of each seat. The grid pattern 408 may have a plurality of openings 410. The openings 410 may be big enough to allow electronic components on the package substrates to expose through the grid pattern 408. In the embodiment shown in FIG. 4B, the grid pattern 408 has two ribs that extend in parallel with each other between a pair of edges of the frame 406. The ribs and the edges of the frame 406 define three openings 410 which expose the electronic components. It can be appreciated that the grid pattern 408 may have more ribs or may have other layouts.

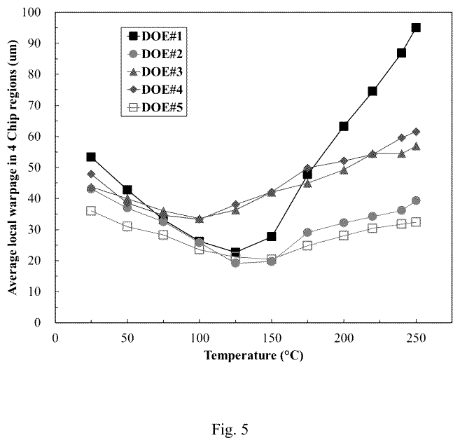

FIG. 5 is a test result comparing the warpage of a package substrate held by a conventional device (DOE #1) without magnetic interactions in the active region of the package substrate with the warpages of package substrates held by four devices (DOE #2 to DOE #5) according to some examples of the present application. The devices according to the examples of the present application all have magnets embedded in its lower jigs, differing only in the density, strength and/or layout of the magnets. As can be seen from FIG. 5, under a high temperature such as 200 centi-degrees or higher which are generally appropriate for a reflow process, all the four devices according to the examples of the present application can achieve better warpage control, for both local warpage or global warpage, than the conventional device. In that case, stretch or non-wetting for solder bumps can be significantly reduced for the package substrates held by the devices according to the examples of the present application.

While the devices for holding a package substrate of the present application is described in conjunction with corresponding figures, it will be understood by those skilled in the art that modifications and adaptations to the device may be made without departing from the scope of the present invention.

The discussion herein included numerous illustrative figures that showed various portions of the devices for holding a package substrate. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A device for holding a package substrate, the device comprising:
a lower jig comprising a base material, and magnets embedded within the base material; and
an upper jig comprising a frame and a grid pattern inside the frame, wherein the frame has a skirt portion that defines a gap between the lower jig and the grid pattern to accommodate the package substrate, and wherein the grid pattern is attractable by the magnets such that when the upper jig is placed on the lower jig to accommodate the package substrate, the grid pattern is in contact with the package substrate to apply a pressure to the package substrate due to a magnetic interaction between the magnets and the grid pattern.

2. The device of claim 1, wherein the upper jig is at least partially formed of a ferromagnetic material.

3. The device of claim 1, wherein the grid pattern has a plurality of ribs that are in contact with the package substrate when the upper jig is placed on the lower jig to accommodate the package substrate, and the grid pattern defines openings for exposing electronic components attached on the package substrate from the upper jig.

4. The device of claim 3, wherein the plurality of ribs are aligned with the magnets of the lower jig when the upper jig is placed on the lower jig to accommodate the package substrate.

5. The device of claim 1, wherein the grid pattern comprises a cover plate and a plurality of protrusions that extend from the cover plate, and wherein the plurality of protrusions are in contact with the package substrate when the upper jig is placed on the lower jig to accommodate the package substrate.

6. The device of claim 5, wherein the cover plate defines cavities for accommodating the electronic components when the upper jig is placed on the lower jig to accommodate the package substrate.

7. The device of claim 1, wherein the magnets are further aligned with the frame to attract the frame to the package substrate to apply a pressure to the package substrate.

8. The device of claim 1, wherein each of the magnets has a distance of 0.2 mm to 20 mm to a top surface of the lower jig.

9. A device for holding package substrates, the device comprising a plurality of seats each comprising:
a lower jig comprising a base material, and magnets embedded within the base material; and
an upper jig comprising a frame and a grid pattern inside the frame, wherein the frame has a skirt portion that defines a gap between the lower jig and the grid pattern to accommodate the package substrate, and wherein the grid pattern is attractable by the magnets such that when the upper jig is placed on the lower jig to accommodate the package substrate, the grid pattern is in contact with the package substrate to apply a pressure to the package substrate due to a magnetic interaction between the magnets and the grid pattern.

10. The device of claim 9, wherein the upper jig is at least partially formed of a ferromagnetic material.

11. The device of claim 9, wherein the grid pattern of each seat has a plurality of ribs that are in contact with the package substrate when the upper jig is placed on the lower jig to accommodate the package substrate, and the grid pattern defines openings for exposing electronic components attached on the package substrate from the upper jig.

12. The device of claim 11, wherein the plurality of ribs of the grid pattern of each seat are aligned with the magnets of the lower jig of each seat when the upper jig is placed on the lower jig to accommodate the package substrates.
